(19) United States
(12) Patent Application Publication
(10) Pub. No.: US 2013/0065501 A1
(43) Pub. Date: Mar. 14, 2013

(54) AIR VENT AND SERVER RACK

(71) Applicant: Shi-Feng Wang, Shanghai City (CN)

(72) Inventor: Shi-Feng Wang, Shanghai City (CN)

(73) Assignee: INVENTEC CORPORATION, Taipei City (TW)

(21) Appl. No.: 13/402,448

(22) Filed: Feb. 22, 2012

(30) Foreign Application Priority Data
Sep. 8, 2011 (CN) 201110265400.1

(51) Int. Cl. H05K 7/20; F24F 11/04; F24F 13/14; F24F 7/007

(52) U.S. Cl. 454/184; 454/256; 454/344; 454/335; 454/345

(57) ABSTRACT

A gravity air vent and a server rack having the same are provided. The server rack includes at least a rack main body and at least a fan module. The fan module is assembled on a side surface of the rack main body and has an air inlet corresponding to the fan module. The air vent includes a frame and at least one covering plate. The covering plate is pivotally connected to the frame and operable of be opened or closed relatively to the frame to expose or cover the air inlet.

### CROSS-REFERENCE TO RELATED APPLICATION

This application claims the priority benefit of China application serial no. 201110265400.1, filed Sep. 8, 2011. The entirety of the above-mentioned patent application is hereby incorporated by reference herein and made a part of this specification.

### BACKGROUND OF THE INVENTION

1. Field of the Invention

The invention relates to a server rack having an air vent. Particularly, the invention relates to a server rack that includes cooling fan modules and having corresponding air vents.

2. Description of Related Art

A server is a computer located in the core of a network system to service all other connected computers. A server computer provides network users their needed storage and printing services. It also enables all network clients to share the resources within the network environment. The basic structure of a server computer is quite similar to a Personal Computer which consists of one or more CPUs, Memory, Input/Output devices and other components. The components are connected to an internal Bus which connects to the CPU(s) and Memory through a North-Bridge controller chip and connects to Input/Output devices through a South-Bridge controller chip. The server chassis has evolved through three generations: the tower chassis, the rack mounted chassis (which provides good centralization), and the blade server (which provides high density computing capability).

Rack mounted servers, for example, have standardized outside dimensions which fit standard sized racks so that their cabinets can be standardized also. That is, rack mounted servers are an optimized version of tower servers. The purpose of its design is to reduce to the minimum the amount of space taken up by the servers. Most professional network equipments such as switches, routers and hardware firewalls have adopted rack mounted structure. They are flat like desk drawers. A server rack has a standard width of 19 inches. Height is measured in the unit of U where 1U is 1.75 inches or 44.45 mm. Heights such as 1U, 2U, 4U, 5U, 7U are commonly used with rack mounted servers.

The size of a typical cabinet also conforms to industry standards, usually from between 22U to 42U. Inside the cabinet, at each U heights, there are removable sliding support structures. Users may make adjustments according to the height of his network equipments such as servers, routers and disk array drives. When the equipment is installed into rack and cabinet, all of their input/output cables are brought out from the rear of cabinet (rack mounted servers have their input/output interfaces in the rear also). All cables are then placed within the cable conduit of the cabinet. Labels are attached to the cables for easier maintenance and management.

Generally speaking, fan modules are installed in the server rack for cooling function. A server rack must have air inlets to allow air flows generated by fan modules so that an appropriate cooling function is achieved. However, when the fan modules are not in operation, dust and other particles from the outside environment may enter a rack server by way of these air inlets, so that dirt accumulated upon the components inside servers and affect their normal operation.

### SUMMARY OF THE INVENTION

The invention is directed to an air vent which can prevent dust and other particles from entering the server rack.

The invention is directed to an air vent having a movable covering device which can prevent dust and other particles from entering the server rack.

The invention provides a server fan module air vent. The air vent is used in conjunction with a fan module. The air vent is disposed at an air inlet of the fan module, and the air vent includes a frame and at least one movable covering plate. The covering plate is pivotally connected to the frame and operable to be opened or closed relatively to the frame to expose or cover the air inlet.

In one embodiment of the invention, the fan module is a suction fan module. When the suction fan module is in operation, an air flow is generated by the suction fan module to pull air through the air vent.

In one embodiment of the invention, the frame has an opening aligned to the air inlet, and the covering plate is pivoted in the opening and suitable of being pivoted relatively to the frame to expose or cover the air inlet.

In one embodiment of the invention, each air vent has exactly one covering plate. A top side of the covering plate is pivoted on the frame. The covering plate and/or the frame has a position-limiting device. When the fan module is in suction state and generates negative air pressure upon the covering plate, the covering plate uses the top side as axis to pivot toward the fan module such that the opening is exposed. When the fan module is not in operation and stops generating negative air pressure upon the covering plate, the covering plate under gravitational pull covers the opening, and the position-limiting device stops the covering plate from being pivoted in a direction away from the fan module.

In one embodiment of the invention, each air vent has multiple covering plates forming a gravity shutter structure.

In one embodiment of the invention, a top side of each of the covering plates is pivoted on the frame. When the fan module is in suction state and generates negative air pressure upon the covering plates, the covering plates use their top sides as axes to pivot toward the fan module such that the opening is exposed. When the fan modules are not in operation and stops generating negative air pressure upon the covering plates, the covering plates under gravitational pull cover the openings, and except for the one covering plate on the top, the top side of each of the remaining covering plates stops the neighbouring covering plate on top from being pivoted in a direction away from the fan module.

In one embodiment of the invention, the one covering plate located farthest down and/or the frame has a position-limiting device such that when the fan module is not in operation, the position-limiting device stops the covering plate from being pivoted in a direction away from the fan module.

The invention also provides a server rack including a rack main body, at least one fan module, and at least one air vent. The fan module is disposed on one side surface of the rack main body. The air vent is disposed on the side surface of the rack main body and corresponding to the air inlet of the fan module. The air vent includes a frame and at least one covering plate. The covering plate is pivotally connected to the frame and suitable for being opened or closed relatively to the frame to expose or cover the air inlet.

In one embodiment of the invention, the fan module is a suction fan module. When the suction fan module is in operation, an air flow is generated by the suction fan module to pull air through the air vent.

In one embodiment of the invention, the frame has an opening aligned to the air inlet. The covering plate is pivoted in the opening and suitable of being pivoted relatively to the frame to expose or cover the air inlet.

In one embodiment of the invention, each air vent has exactly one covering plate. A top side of the covering plate is pivoted on the frame. The covering plate and/or the frame has a position-limiting device. When the fan module is in suction state and generates negative air pressure upon the covering plate, the covering plate uses the top side as an axis to pivot toward the fan module such that the opening is exposed. When the fan module is not in operation and stops generating negative air pressure upon the covering plate, the covering plate under gravitational pull covers the opening, and the position-limiting device stops the covering plate from being pivoted in a direction away from the fan module.

In one embodiment of the invention, each air vent comprises a plurality of covering plates forming a gravity shutter structure.

In one embodiment of the invention, a top side of each of the covering plates is pivoted on the frame. When the fan module is in suction state and generates negative air pressure upon the covering plates, each covering plate uses the top side as axis to pivot toward the fan module such that the opening is exposed. When the fan modules are not in operation and stop generating negative air pressure upon the covering plates, the covering plates under gravitational pull cover the openings, and except for the one covering plate on the top, the top side of each of the rest covering plates stops the neighbouring covering plate on top from being pivoted in a direction away from the fan module.

In one embodiment of the invention, the one covering plate located farthest down and/or the frame has a position-limiting device such that when the fan module is not in operation, the position-limiting device stops the covering plate from being pivoted in a direction away from the fan module.

In one embodiment of the invention, there are a plurality of fan modules and corresponding air vents. The air vents correspond to the fan modules respectively. Each of the air vents has a frame with at least one opening. Each of the openings is aligned to the corresponding air inlet. Each of the covering plates is pivoted in the opening and suitable of being pivoted relatively to the frame to expose or cover the corresponding air inlet. When some of the fan modules are removed from the rack main body and stop from generating negative air pressure upon the corresponding covering plates, the corresponding covering plates under gravitational pull cover the corresponding openings.

From the above descriptions, the invention provides an air vent suitable of being opened or closed to expose or cover the air inlet of the fan module. Thereby, when the fan module is in operation, the movable covering device exposes the air inlet such that the fan module generates air flow to the inside of the rack main body for cooling function. When the fan module is not in operation, the movable covering device covers the air inlet such that dust and other particles from outside environment can not enter the inside of the rack main body through the air inlet, thereby ensures the normal functioning of components inside the server rack.

In order to make the aforementioned and other features and advantages of the invention comprehensible, exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three dimensional drawing which shows the server rack according to an embodiment of the invention.

FIG. 2 is a three dimensional drawing which shows from another viewpoint some components of the server rack of FIG. 1.

FIG. 3 is a three dimensional drawing of the air vent in another viewpoint.

### DETAILED DESCRIPTION OF DISCLOSED EMBODIMENTS

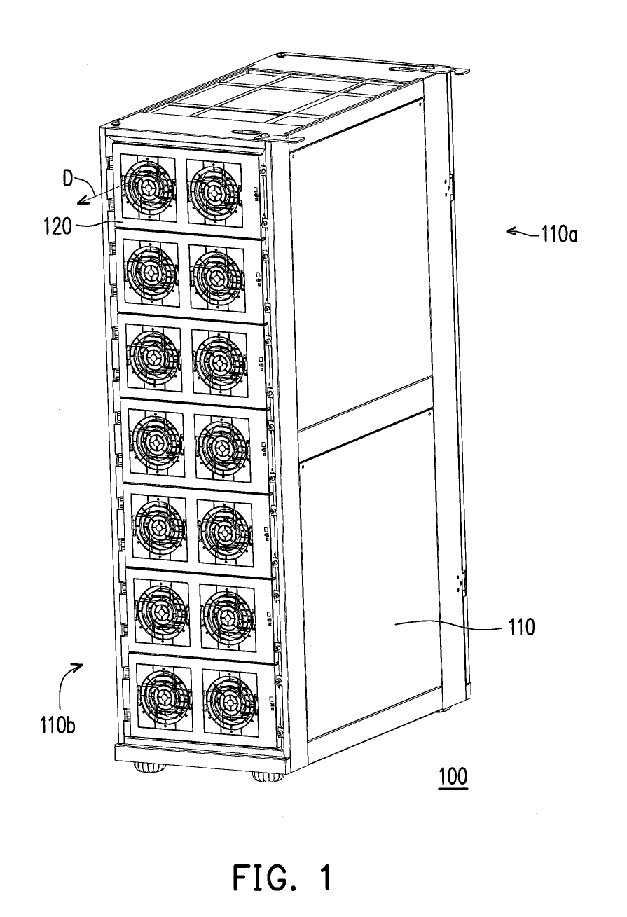

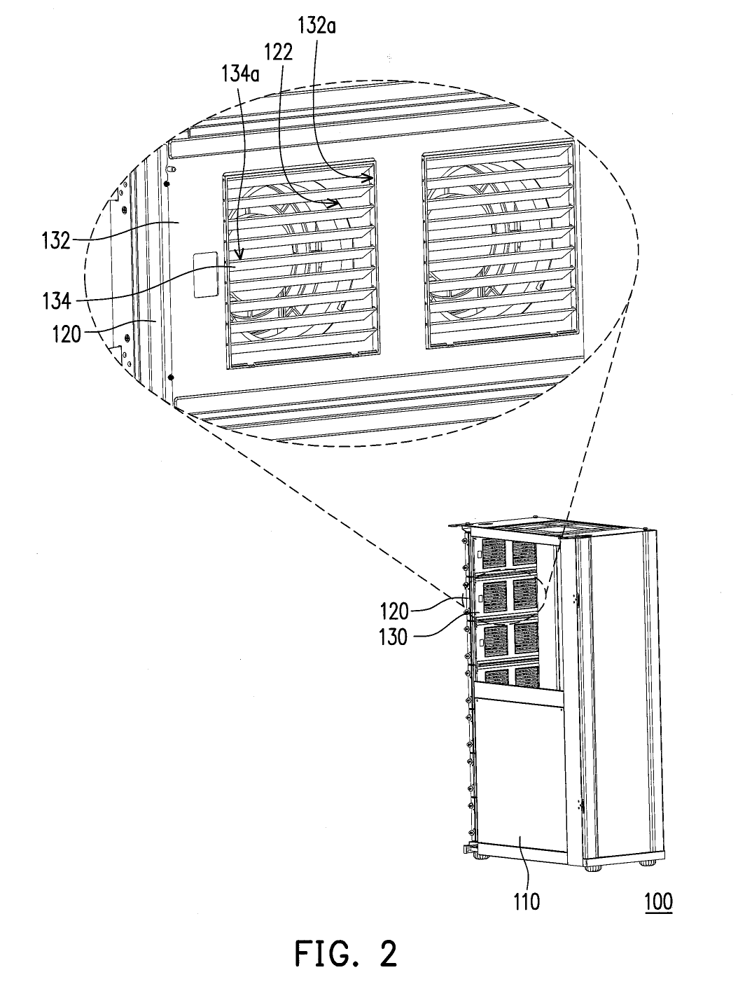

FIG. 1 is a three dimensional drawing which shows a server rack according to an embodiment of the invention. FIG. 2 is a three dimensional drawing which shows from another viewpoint some components of the server rack of FIG. 1. Referring to FIGS. 1 and 2, in this embodiment, the server rack 100 includes a rack main body 110, several fan modules 120 and several movable covering devices 130. The rack main body 110 has a front side surface 110a and a back side surface 110b opposite to each other. The fan modules 120 are disposed on the back side surface 110b of the rack main body 110, and each of the fan modules 120 has at least one air inlet 122. Air vents 130 are disposed on the back side surface 110b of the rack main body 110, and correspond to the air inlets 122 respectively. Each of the fan modules 120 is a suction fan module. When the suction fan module is in operation, an air flow is generated in a direction D away from the air vent 130 so as to cool the electronic components inside the server rack 100.

Each of the air vents 130 includes a frame 132 and at least one pivotally movable horizontal covering plate or slat 134 (multiple covering plates are shown in drawing). The frame 132 is disposed or mounted on the corresponding fan module 122 and faces the inside of the rack main body 110 as shown in FIG. 2. The covering plate or slat 134 is connected to the frame 132 and suitable of being opened or closed relatively to the frame 132 to expose or cover the air inlet 122.

From the above descriptions, when the fan modules 120 are in operation, the air vents 130 expose air inlets 122 such that fan modules 120 generate air flow to the inside of the rack main body 110 for cooling function. When the fan modules 120 are not in operation, the covering plates or slats 134 of the air vents 130 cover the air inlets 122 such that dust and other particles from outside environment can not enter the inside of the rack main body 110 through the air inlets 122, thereby ensuring the normal functioning of components inside the server rack 100.

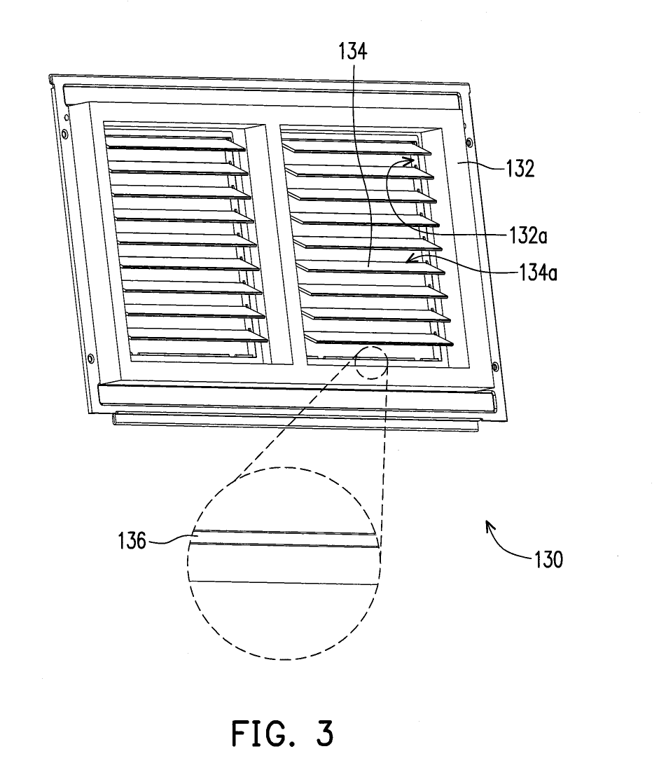

FIG. 3 is a three dimensional drawing of the air vent of FIG. 2. in another viewpoint. Referring to FIGS. 2 and 3, in this embodiment, the frame 132 has an opening 132a aligned to the corresponding air inlet 122. The covering plate 134 is pivoted in the opening 132a and suitable of being pivoted relatively to the frame 132 to expose or cover the opening 132a (In FIG. 3, the opening 132a is exposed).

In this embodiment, there are multiple covering plates or slats 134 that form a gravity shutter or louver structure. A top side of each of the covering plates 134 is pivoted on the frame 132. When the fan modules 120 are in suction state and generate negative air flow upon the covering plates 134, each of the covering plates 134 uses its top side 134a as an axis to pivot toward the fan module 120 such that the opening 132a is exposed. Thereby air flow generated by the fan modules 120 can flow through the openings 132a to cool the electronic components inside the server rack 100. When the fan modules 120 are not in operation and stop generating negative air pressure upon the covering plates 134, the covering plates 134 under gravitational pull cover the opening 132a, and except the uppermost plate 134, the top side 134a of each of the other covering plates 134 stops the covering plate 134 on top of it from being pivoted in a direction away from the fan module 120. The one covering plate 134 located farthest down and/or the frame 132 has a position-limiting device 136 (FIG. 3 shows the frame 132 including the position-limiting device 136), such that when the fan module 120 is not in operation, the position-limiting device 136 stops the covering plate 134 located at the farthest down position from being pivoted in a direction away from the fan module 120. This structure ensures that the opening 132a is covered by the covering plates 134. Therefore, when some of the fan modules 120 are removed from the rack main body 110 and stop generating air flow upon the corresponding covering plates 134, the corresponding covering plates 134 under gravitational pull cover the corresponding openings 132a, such that dust particles are prevented from entering through the corresponding openings 132a to contaminate the components inside the server rack 100.

However, the invention is not limited by the number of the covering plates and the structure of the air vent as described in the above embodiments. In other embodiments, the number of the covering plates can vary as necessary, and the structure of the air vent can be in forms other than shutter structure. For example, in another embodiment, the number of the covering plates can be one and a single covering plate is used to cover the opening of the frame. The single covering plate device, its arrangement and function are similar to the covering plate 134 shown in FIGS. 2 and 3 which is suitable to pivot toward the fan module to expose the opening of the frame when acted upon by the air flow generated by the fan module, and is suitable to drop down under gravitational pull to cover the opening when the fan module is not in operation. Furthermore, the position limiting device 136 as shown in FIGS. 2 and 3 may be included in the frame to stop the above described single covering plate from being pivoted in a direction away from the fan module.

In summary, the invention provides a gravity air vent that opens the air inlet when the fan is on and closes it when the fan is off. Therefore, when the fan modules are in operation, the movable covering device exposes the air inlet such that air flow generated by the fan modules can flow to the inside of the rack main body for cooling function. When the fan modules are not in operation, the air vent covers the air inlet such that dust and other particles from outside environment can not enter the inside of the rack main body through the air inlet, thereby ensuring the normal functioning of components inside the server rack.

It will be apparent to those skilled in the art that various modifications and variations can be made to the structure of the invention without departing from the scope or spirit of the invention. In view of the foregoing, it is intended that the invention covers modifications and variations of this invention provided they fall within the scope of the following claims and their equivalents.

What is claimed is:

1. A server fan module air vent disposed at an air inlet of a fan module, and the server fan module air vent comprising:
a frame; and
at least one covering plate, connected to the frame and operable to be opened or closed relatively to the frame to expose or cover the air inlet.

2. The server fan module air vent as claimed in claim 1, wherein the fan module is a suction fan module, and when the suction fan module is in operation, an air flow is generated by the suction fan module to pull air through the server fan module air vent.

3. The server fan module air vent as claimed in claim 1, wherein the frame has an opening aligned to the air inlet, and the covering plate is pivoted in the opening and suitable of being pivoted relatively to the frame to expose or cover the air inlet.

4. The server fan module air vent as claimed in claim 3, wherein the air vent has exactly one covering plate, a top side of the covering plate is pivoted on the frame, and the covering plate and/or the frame has a position-limiting device;
wherein when the fan module is in a suction state and generates negative air pressure upon the covering plate, the covering plate pivots about an axis located along the top side of the covering plate toward the fan module such that the opening is exposed; and
wherein when the fan module is not in operation and stops generating negative air pressure upon the covering plate, the covering plate under gravitational pull pivots back down to cover the opening, and the position-limiting device stops the covering plate from being pivoted in a direction away from the fan module.

5. The server fan module air vent as claimed in claim 3, wherein the air vent has multiple coverings forming a gravity shutter structure.

6. The server fan module air vent as claimed in claim 5,
wherein a top side of each of the covering plates is pivoted on the frame;
wherein when the fan module is in suction state and generates negative air pressure upon the covering plates, each covering plate pivots about an axis located along the top side of the covering plate toward the fan module such that the opening is exposed; and
wherein when the fan module is not in operation and stops generating negative air pressure upon the covering plates, each covering plate under gravitational pull pivots back down to cover the opening, and except for the one covering plate on the top, the top side of each of the remaining covering plates stops the neighbouring covering plate on top from being pivoted in a direction away from the fan module.

7. The server fan module air vent as claimed in claim 6, wherein the one covering plate located farthest down and/or the frame has a position-limiting device such that when the fan module is not in operation, the position-limiting device stops the one covering plate located farthest down from being pivoted in a direction away from the fan module.

8. A server rack, comprising,
a rack main body,
at least one fan module, disposed on one side surface of the rack main body; and
at least one air vent, disposed on the side surface of the rack main body and corresponding to an air inlet of the fan module, wherein the movable covering device comprises:
a frame; and
at least one covering plate, connected to the frame and operable to be opened or closed relatively to the frame to expose or cover the air inlet.

9. The server rack as claimed in claim 8, wherein the fan module is a suction fan module, when the suction fan module is in operation, an air flow is generated by the suction fan module to pull air through the air vent.

10. The server rack as claimed in claim 8, wherein the frame has an opening aligned to the air inlet, and the covering plate is pivoted in the opening and suitable of being pivoted relatively to the frame to expose or cover the air inlet.

11. The server rack as claimed in claim 10, wherein the air vent has exactly one covering plate, a top side of the covering plate is pivoted in the frame, and the covering plate and/or the frame has a position-limiting device;
wherein when the fan module is in a suction state and generates negative air pressure upon the covering plate, the covering plate pivots about an as axis located along the top side of the covering plate toward the fan module such that the opening is exposed; and
wherein when the fan module is not in operation and stops generating negative air pressure upon the covering plate, the covering plate under gravitational pull pivots back down to cover the opening, and the position-limiting device stops the covering plate from being pivoted in a direction away from the fan module.

12. The server rack as claimed in claim 10, wherein the air vent has multiple covering plates forming a gravity shutter structure.

13. The server rack as claimed in claim 12, wherein a top side of each of the covering plates is pivoted on the frame;
wherein when the fan module is in suction state and generates negative air pressure upon the covering plates, each covering plate pivots about an axis located along the top side of the covering plate toward the fan module such that the opening is exposed; and
wherein when the fan module is not in operation and stops generating negative air pressure upon the covering plates, each covering plate under gravitational pull covers the opening, and except for the one covering plate on the top, the top side of each of the remaining covering plates stops the neighbouring covering plate on top from being pivoted in a direction away from the fan module.

14. The server rack as claimed in claim 13, wherein the one covering plate located farthest down and/or the frame has a position-limiting device such that when the fan module is not in operation, the position-limiting device stops the one covering plate located farthest down from being pivoted in a direction away from the fan module.

15. The server rack as claimed in claim 8, comprising a plurality of fan modules and a plurality of corresponding air vents having corresponding openings aligned to its corresponding air inlet, and each air vent has one or more covering plates that are pivoted in the opening and operable to pivoted to expose or cover the corresponding air inlet, so that when some of the fan modules are removed from the rack main body and stop generating negative air pressure upon the corresponding covering plates, the corresponding covering plates under gravitational pull cover the corresponding openings.
